(19) United States
(12) Patent Application Publication
(10) Pub. No.: US 2005/0194685 A1
(43) Pub. Date: Sep. 8, 2005

(54) Method for mounting semiconductor chips and corresponding semiconductor chip system

(76) Inventors: Kurt Weiblen, Metzingen (DE); Hubert Benzel, Pliezhausen (DE); Regina Grote, Reutlingen (DE)

Correspondence Address: KENYON & KENYON, ONE BROADWAY, NEW YORK, NY, 10004, US

(21) Appl. No.: 11/065,638

(22) Filed: Feb. 23, 2005

(30) Foreign Application Priority Data
Mar. 4, 2004 (DE) 10 2004 011 203.7

(51) Int. Cl. H01L 23/48; H01L 21/48

(52) U.S. Cl. 257/738; 257/778; 438/108

(57) ABSTRACT

A method for mounting semiconductor chips includes the steps of: a) providing a semiconductor chip having a surface that has a diaphragm region and a peripheral region, the peripheral region having a mounting region; b) providing a substrate which has a surface having a recess; c) mounting the mounting region of the semiconductor chip using a flip-chip technique onto the surface of the substrate in such a way that an edge of the recess lies between the mounting region and the diaphragm region; and d) underfilling the mounting region using an underfilling component, the edge of the recess being used a demarcation region for the underfilling component, so that no underfilling component is able to get into the diaphragm region. Also provided is a corresponding semiconductor chip system.

### FIELD OF THE INVENTION

The present invention relates to a method for mounting semiconductor chips and a corresponding semiconductor chip system.

### BACKGROUND INFORMATION

FIG. 7 shows a conventional method of mounting semiconductor chips and a corresponding semiconductor chip system in cross sectional view. In FIG. 7, reference numeral 100 denotes a TO8 base produced, for example, from Kovar. Reference numeral 5 is a micromechanical silicon pressure-sensor chip having piezoresistive transformer elements 51 that are accommodated on a diaphragm 55. To produce diaphragm 55, a cavity 58 is introduced onto the back of respective silicon pressure sensor chip 5, for instance, by anisotropic etching, e.g., using KOH or TMAH. Alternatively, diaphragm 55 may also be produced by trench-etching.

Sensor chip 5 may be made up of a pure resistance bridge having piezoresistive resistors, or may be combined with an evaluation circuit which is integrated, together with the piezoresistors, in a semiconductor process. A glass base 140 made of sodium-containing glass, which is anodically bonded to the back of chip 5, is used to reduce mechanical stress caused by solder or adhesive 70 by which glass base 140 is mounted on TO8 base 100. Reference numeral 53 in FIG. 7 denotes a bonding pad of an integrated circuit 52 (not further shown), the bonding pad being connected via a bonding wire 60 to an electrical connecting device 130, which in turn is insulated from TO8 base 100 by an insulating layer 131. Glass base 140 has a through hole 141 which connects cavity 58, via a through hole 101 of TO8 base 100 and a connecting device 120 affixed thereon, to externally prevailing pressure P. The construction shown in FIG. 7 is usually also hermetically welded with a metal cap (not shown).

However, such a construction has the disadvantage that it is cumbersome, and that problems frequently arise with the hermetic enclosing of sensor chip 5, for instance, because of leaky welding seams or the like. Since the TO8 housing and the silicon have different thermal coefficients of expansion, mechanical stresses are created in response to temperature changes, which are measured as interference signals by piezoresistors.

FIG. 8 shows another conventional method of mounting semiconductor chips and a corresponding semiconductor chip system in cross-sectional view. This second example provides attaching a sensor chip 5, via a glass base 140′ that has no through hole, to a substrate 1 made of ceramic, and to passivate it using a gel 2 to protect it from environmental influences. Additionally provided above the chip system on substrate 1 is a protective cap 13 that has a through hole 15 for pressure P to be applied. Glass base 140′, in this example, also has no through hole, since pressure P is applied from the other side.

When such a gel 2 is used, the maximum pressure is disadvantageously determined by gel 2, since gas diffuses into gel 2, and, if there is a sudden reduction in pressure, gas bubbles are created in gel 2 which destroy gel 2.

### SUMMARY OF THE INVENTION

The method according to the present invention for mounting semiconductor chips and the corresponding semiconductor chip system have the advantage over the known art in that a construction that is simple, cost-effective and insensitive to stress is made possible.

The present invention utilizes an overhanging type of construction of a sensor chip on a substrate having a recess, with the aid of a flip-chip mounting technique, a mechanical decoupling of the sensor chip being provided by the lateral overhanging.

Available production processes may be maintained, for the most part, such as the semiconductor process for sensor components and/or evaluation circuit components and for sensor housing parts.

Electrical die testing in the wafer composite is possible, as is the end-of-production-line adjustment after assembly on the carrier. The method according to the present invention also makes possible a space-saving construction of sensor chip and evaluation circuit.

According to one example embodiment of the present invention, pluralities of bondpads are provided in the mounting region, which are mounted on the surface of the substrate via a soldering or adhesive connection.

According to another example embodiment of the present invention, the recess extends to below the diaphragm region. This has the advantage that no foreign bodies are able to become wedged in below the diaphragm region.

According to another example embodiment of the present invention, the sensor chip is bonded on its rear surface to a glass base. This increases the resistance to bending. Besides, one may enclose a vacuum between the glass base and the sensor chip.

According to one further example embodiment of the present invention, in the peripheral region, one or more support bases are provided, which are provided lying on the surface of the housing. This support base prevents tilting in response to the flip-chip mounting.

According to one further example embodiment of the present invention, the substrate is a part of a prefabricated housing. According to yet another example embodiment of the present invention, the housing is a pre-mold housing made of plastic, into which a lead frame is molded. Such housings are particularly cost-effective.

According to one additional further example embodiment of the present invention, the housing has an annular sidewall region that surrounds the sensor chip, and is closed above the sensor chips by a cover having a through hole.

According to a further example embodiment of the present invention, an additional semiconductor chip is mounted in the housing, completely molded in.

### BRIEF DESCRIPTION OF THE DRAWINGS

FIG. 1 a illustrates a first example embodiment of the method according to the present invention for mounting semiconductor chips and a corresponding semiconductor chip system in a side-plane cross sectional view.

FIG. 1b illustrates the first example embodiment of the method according to the present invention for mounting semiconductor chips and a corresponding semiconductor chip system in a top-plane cross sectional view.

FIG. 2 is a cross-sectional view illustrating a second example embodiment of the method according to the present invention for mounting semiconductor chips and a corresponding semiconductor chip system.

FIG. 3 is a cross-sectional view illustrating a third example embodiment of the method according to the present invention for mounting semiconductor chips and a corresponding semiconductor chip system.

FIG. 4 is a cross-sectional view illustrating a fourth example embodiment of the method according to the present invention for mounting semiconductor chips and a corresponding semiconductor chip system.

FIG. 5 is a cross-sectional view illustrating a fifth example embodiment of the method according to the present invention for mounting semiconductor chips and a corresponding semiconductor-chip system.

FIG. 6 is a cross-sectional view illustrating a sixth example embodiment of the method according to the present invention for mounting semiconductor chips and a corresponding semiconductor chip system.

FIG. 7 is a cross-sectional view illustrating a first example of a conventional method of mounting semiconductor chips and a corresponding semiconductor chip system.

FIG. 8 is a cross-sectional view illustrating a second example of a conventional method of mounting semiconductor chips and a corresponding semiconductor chip system.

### DETAILED DESCRIPTION

In the figures discussed below, identical reference numerals denote identical or functionally identical components.

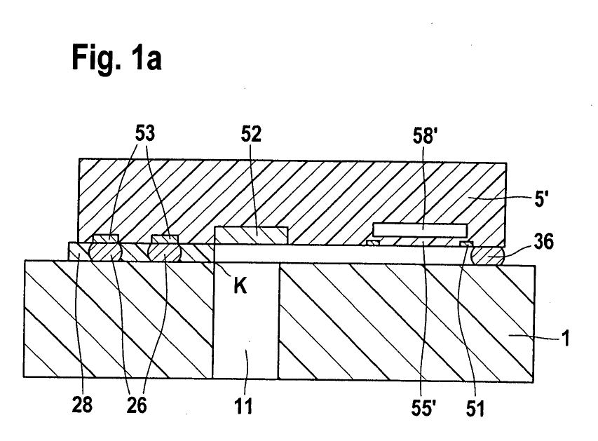

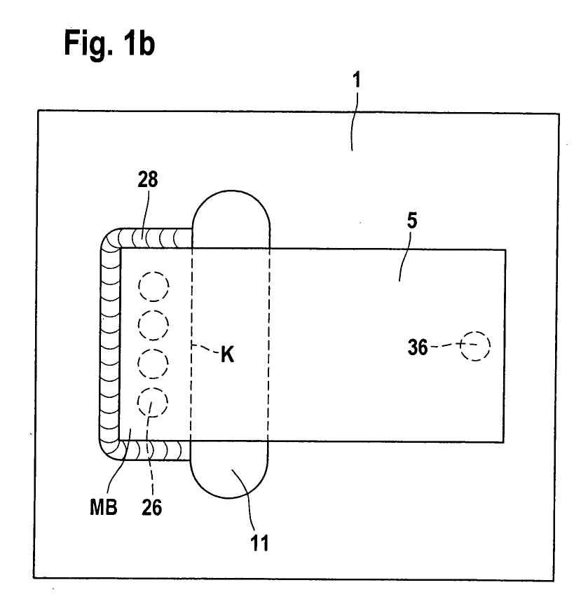

FIGS. 1a and 1b illustrate a first example embodiment of the method according to the present invention for mounting semiconductor chips and a corresponding semiconductor chip system (FIG. 1a shows a side-plane cross-sectional view, and FIG. 1b shows a top-plane cross sectional view).

In the first example embodiment shown in FIGS. 1a and 1b, sensor chip 5′ is a surface micromechanical sensor chip which is produced, for example, according to the method described in German patent document DE 100 32 579, and which sensor chip has an integrated cavity 58′ above a diaphragm region 55′.

Substrate 1 has a recess 11, next to which sensor chip 5′ is mounted in flip-chip technique in an overhanging fashion. For the mounting, bondpads 53 of sensor chip 5′ are soldered in mounting region MB onto bondpads of substrate 1, using a solder or adhesive connection, such as solder balls 26.

Mounting region MB also has an underfilling 28 made of an insulating plastic material, and edge K of recess 11, which lies between mounting region MB and diaphragm region 55′, is used as demarcation edge for underfilling 28 during the mounting process. Demarcation edge K ensures that underfilling 28 is not able to get into or under diaphragm region 55′. Diaphragm region 55′ of sensor chip 5′ thereby extends outwards laterally next to strip-shaped mounting region MB, so that the pressure medium is able to reach diaphragm region 55′ without hindrance. In diaphragm region 55′, sensor chip 5′ is passivated on the surface by a layer (not shown), such as a nitride layer, which acts as a secure medium protection. In mounting region MB, sensor chip 5′ is protected from corrosion by underfilling 28.

An optional support base 36, provided at the peripheral region of diaphragm region 55′ opposite to mounting region MB, is intended to prevent the tilting of sensor chip 5′ during the flip-chip mounting. This support base 36 may be provided either on the upper side of chip 5′ or on the opposite surface of substrate 1, and has no solder surface, so that, in this region, sensor chip 5 rests only on the upper side of substrate 1, but is not firmly connected to it, so that stress influences are avoided in this region.

In FIG. 1b, strip-shaped mounting region MB of sensor chip 5, having underfilling 28 and the solder balls 26, is clearly recognizable. Mounting region MB is substantially smaller than the overall surface of sensor chip 5, which results in a construction having a diving-board configuration. Recess 11 also extends beyond the width extension of sensor chip 5′. In this first specific embodiment, recess 11′ is developed in substrate 1 as a narrow trench, which does not extend right up to, or below, diaphragm region 55′ of sensor chip 5′. However, this does not have to be the case, and, in principle, the recess may also extend to below the diaphragm region, as will be discussed later.

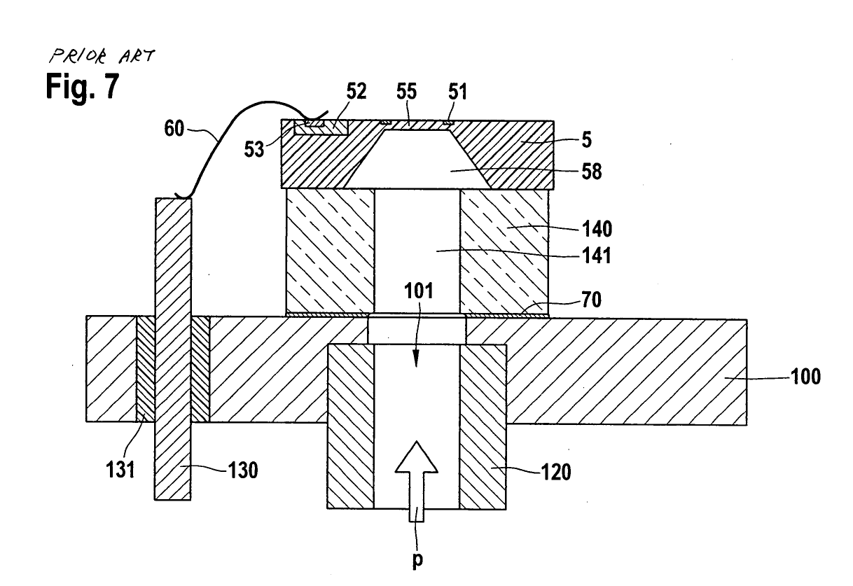

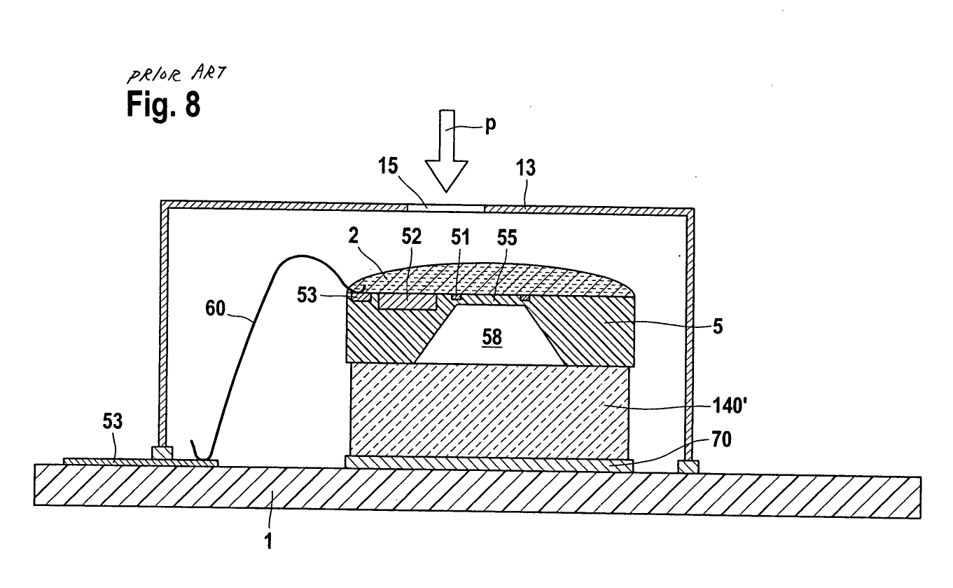

In this example embodiment of the present invention shown in FIGS. 1a and 1b, the glass base of the conventional configuration shown in FIG. 7 or 8 may be completely omitted, since the lateral projection of surface micromechanical sensor chip 5′ next to strip-shaped mounting region MB already makes possible the diminution of stress that is created by different thermal coefficients of expansion of silicon and glass at the connections using solder balls 26 and underfilling 28.

It should be further noted that the construction shown in FIGS. 1a and 1b may be packaged in a housing (not shown in FIGS. 1a and 1b).

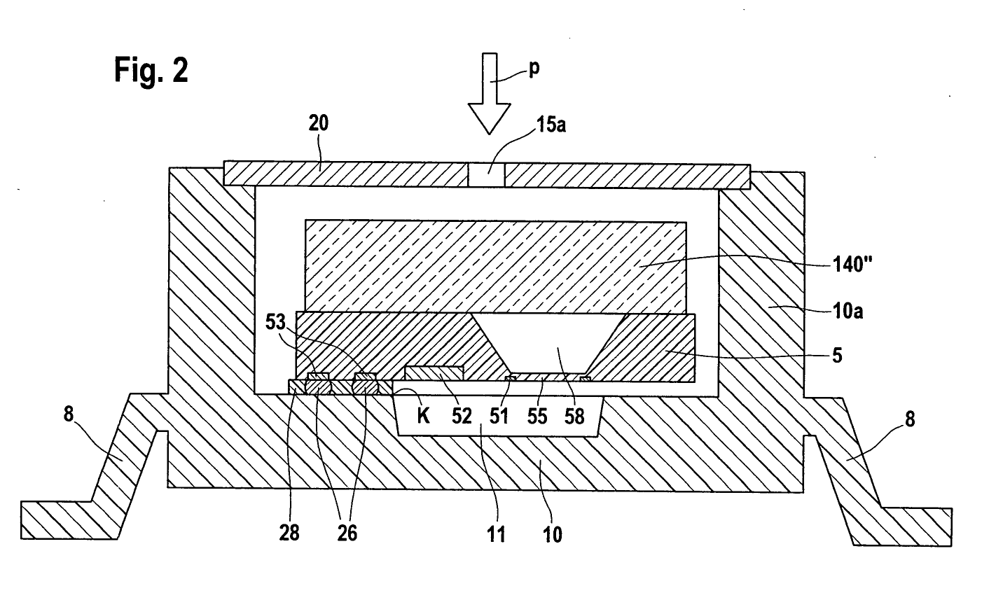

FIG. 2 shows a cross-sectional view of a second example embodiment of the method according to the present invention for mounting semiconductor chips and a corresponding semiconductor chip system.

In the second example embodiment, the substrate is part of a pre-mold housing 10 made of plastic, from which there extends laterally a lead-frame 8 molded into it. Substrate housing 10 has a recess 11, next to which sensor chip 5 is mounted in flip-chip technique in an overhanging fashion. For the mounting, bondpads 53 of sensor chip 5 are soldered onto bondpads of the pre-mold housing 10, using a solder or adhesive connection, such as solder balls 26.

The minimum separation distance of leadframe 8 in the mounting region of sensor chip 5 is usually greater than the minimum separation distance of bondpads 53 on sensor chip 5. However, since only few bondpads 53 are required on sensor chip 5, such as four pieces for connection to a Wheatstone's bridge, they may be placed as far as necessary from one another.

The mounting region has an underfilling 28 made of an insulating plastic material, and edge K of recess 11, which lies between the mounting region and diaphragm region 55, is used as demarcation edge for underfilling 28 during the mounting process. Demarcation edge K has the function already explained in connection with the first example embodiment illustrated in FIGS. 1a and 1b.

Here, too, sensor chip 5 is passivated on the surface in diaphragm region 55 by a nitride layer (not shown), which acts as secure medium protection. In the mounting region, sensor chip 5 is protected from corrosion by underfilling 28.

Finally, pre-mold housing 10 has an annular sidewall region 10a, on whose upper side a cover 20 is provided, having a through hole opening 15a for the pressure P that is to be applied. Based on the fact that sensor chip 5 is distanced from the upper side of pre-mold housing 10 because of the flip-chip mounting on the side of the peripheral region opposite the mounting region, efficient, non-problematical transmission of applied pressure P to diaphragm region 55 is ensured.

In the present example embodiment shown in FIG. 2, sensor chip 5 is bonded on its rear to a glass base 140″, which may be thinner than in the conventional examples according to FIGS. 7 and 8 that were mentioned at the outset, since the lateral extension of sensor chip 5 next to strip-shaped mounting region already makes possible.the diminution of the stress that is created by the different thermal coefficients of expansion of silicon and glass at the junction with the solder balls 26 and underfilling 28.

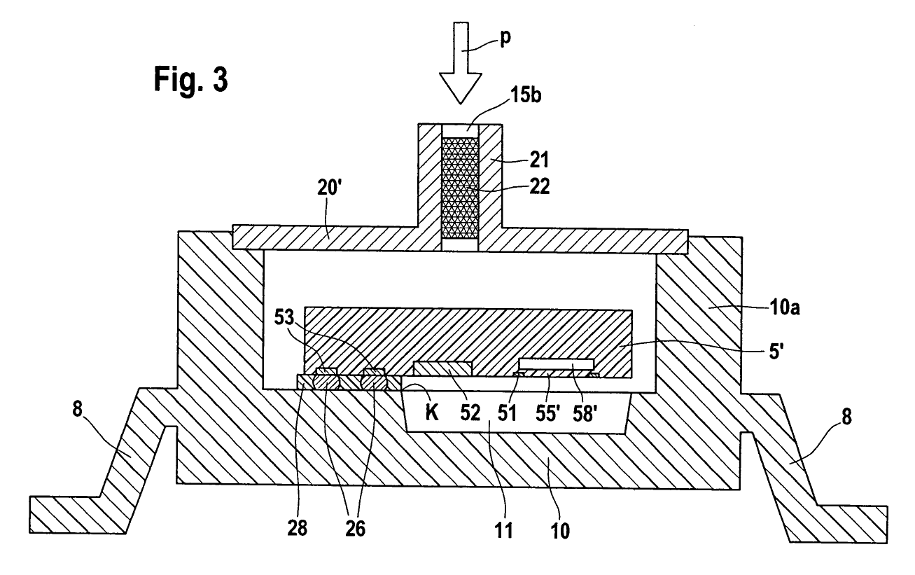

FIG. 3 shows a cross-sectional view of a third example embodiment of the method according to the present invention for mounting semiconductor chips and a corresponding semiconductor chip system.

In the third example embodiment shown in FIG. 3, sensor chip 5′ is also a surface micromechanical sensor chip which was produced, for example, according to the method described in German patent document DE 100 32 579, and which has an integrated cavity 58′ above a diaphragm region 55′.

In this third example embodiment, too, the glass base has been completely omitted, which makes possible a particularly space-saving construction, and a correspondingly lower sidewall region 10a. The mounting using solder balls 26 and underfilling 28 is the same as in the preceding example embodiments shown in FIGS. 1a, 1b, and 2.

In contrast to the preceding example embodiments shown in FIGS. 1a, 1b, and 2, cover 20′ has a pressure-connecting nipple 21, in whose through hole opening 15b an optional filter 22 may be built, which filter prevents particles or liquid media from reaching the inside of the sensor packaging. Thus, for example, it may be prevented that water gets in, which, if there were frost, could sever explosively and thereby destroy sensor chip 5′.

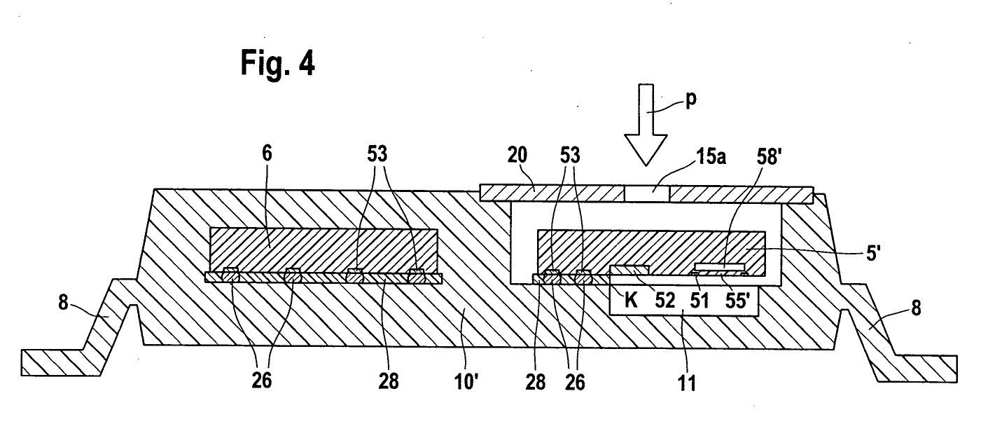

FIG. 4 shows a cross-sectional view of a fourth example embodiment of the method according to the present invention for mounting semiconductor chips and a corresponding semiconductor chip system.

In the fourth example embodiment according to FIG. 4, a housing is provided, which is a combination of mold and pre-mold housing. In the left part of FIG. 4, an evaluation chip 6 is mounted via solder balls in flip-chip technique on lead-frame 8 and is completely encapsulated. In the right part of FIG. 4, there is located the pre-mold region, in which sensor chip 5′ is subsequently mounted in the manner that has already been explained in detail in connection with FIG. 3. Electrical connections between chips 5′ and 6 are made via lead-frame 8, but are not shown in FIG. 4.

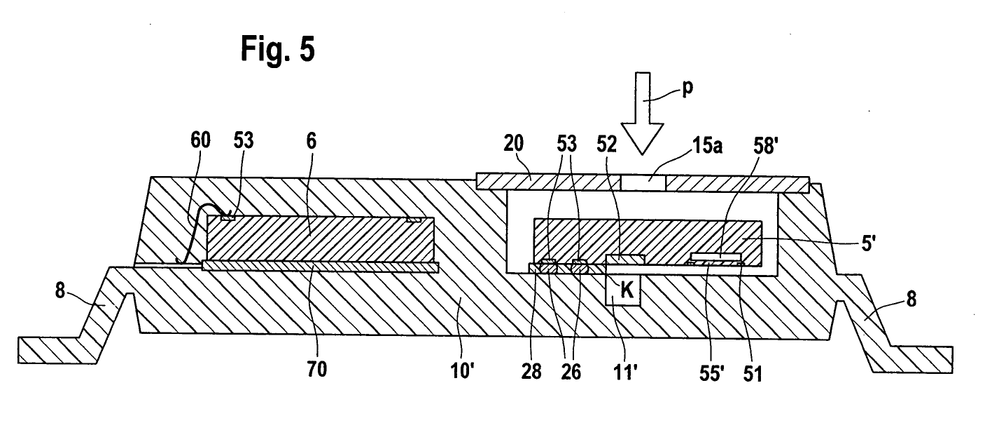

FIG. 5 shows a cross-sectional view of a fifth example embodiment of the method according to the present invention for mounting semiconductor chips and a corresponding semiconductor chip system.

In the fifth example embodiment shown in FIG. 5, in contrast to the fourth example embodiment shown in FIG. 4, evaluation chip 6 is connected to lead-frame 8 via bonding wires 60. This arrangement is advantageous especially for the case in which many electrical connections are needed for evaluation chip 6. For, in this way, the separation distance of bondpads 53 on evaluation chip 6 may be chosen to be small, and that of the corresponding bondpads on lead-frame 8 to be farther apart.

In this specific example embodiment shown in FIG. 5, too, recess 11′ is developed in substrate 10′ as a narrow trench, which does not extend right up to, or below, diaphragm region 55′ of sensor chip 5. The distance of diaphragm region 55′ from the surface of pre-mold housing 10′ may consequently be held low, and therefore one should take care, in such an embodiment, that no particles are able to get into the space between diaphragm region 55′ and pre-mold housing 10′, which could get wedged in there, and could thereby influence the characteristics curve of the sensor chip.

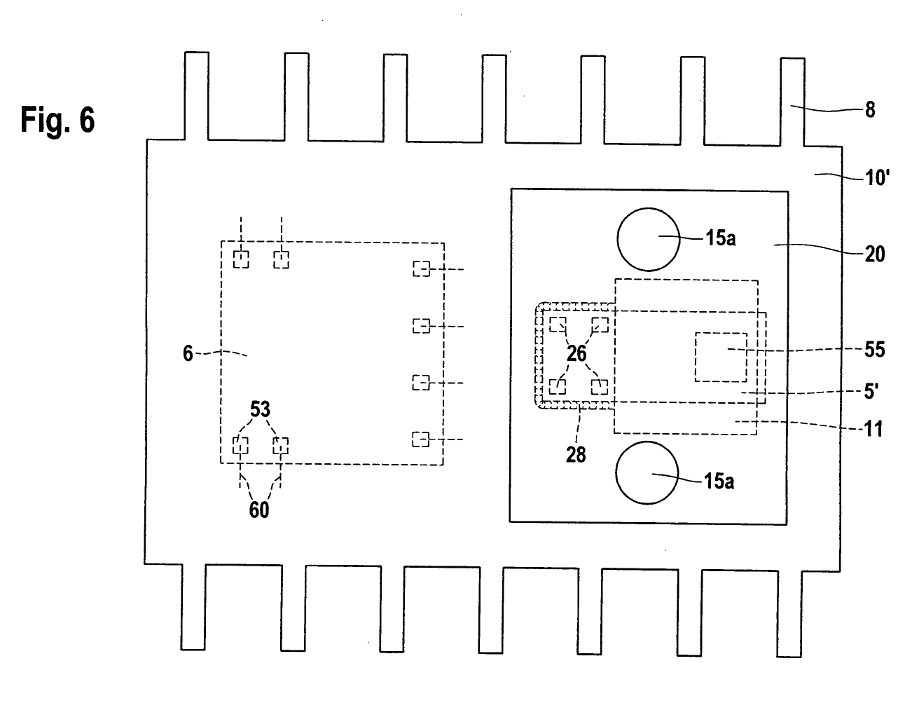

FIG. 6 shows a cross-sectional view of a sixth example embodiment of the method according to the present invention for mounting semiconductor chips and a corresponding semiconductor chip system.

In the example embodiment shown in FIG. 6, the positioning on lead-frame 8 of sensor chip 5′ and evaluation chip 6 is shown. By contrast to the preceding example embodiments, in this sixth example embodiment, two through hole openings 15a are provided for the pressure connection in cover 20.

Although the present invention has been explained above in the light of specific example embodiments, it is not limited to these, but may also be implemented in other ways.

In the above example, only piezoresistive sensor structures were discussed. However, the present invention is also suitable for capacitive or other sensor structures, in which diaphragms are used.

1. A method for mounting semiconductor chips, comprising:
providing a semiconductor chip having a surface that has a first diaphragm region and a peripheral region, the peripheral region including a mounting region;
providing a substrate that has a surface with a recess;
mounting the mounting region of the semiconductor chip using a flip-chip technique onto the surface of the substrate, whereby an edge of the recess lies between the mounting region and the diaphragm region; and
filling an area below the mounting region using an underfilling component, the edge of the recess being used as the demarcation region for the underfilling component so that no underfilling component extends into the diaphragm region.

2. The method as recited in claim 1, wherein in the mounting region a plurality of bondpads are provided for mounting onto the surface of the substrate by one of a soldering and an adhesive connection.

3. The method as recited in claim 2, wherein the semiconductor chip is configured as a sensor chip, and wherein the recess extends to an area below the diaphragm region.

4. The method as recited in claim 3, wherein the semiconductor chip is configured as a sensor chip, and wherein the sensor chip is bonded on its rear surface to a glass base.

5. The method as recited in claim 1, wherein, in the peripheral region, at least one support base is provided lying on the surface of the substrate.

6. The method as recited in claim 3, wherein, in the peripheral region, at least one support base is provided lying on the surface of the substrate.

7. The method as recited in claim 1, wherein the substrate is a part of a prefabricated housing.

8. The method as recited in claim 3, wherein the substrate is a part of a prefabricated housing.

9. The method as recited in claim 8, wherein the housing is a pre-mold housing made of plastic, and wherein a lead-frame is molded into the housing.

10. The method as recited in claim 8, wherein the housing has an annular sidewall region that surrounds the sensor chip, and wherein the housing is closed above the sensor chip by a cover having a through hole opening.

11. The method as recited in claim 9, wherein the housing has an annular sidewall region that surrounds the sensor chip, and wherein the housing is closed above the sensor chip by a cover having a through hole opening.

12. The method as recited in claim 8, wherein an additional semiconductor chip is mounted in the housing by being molded into the housing.

13. A semiconductor chip system, comprising:
a semiconductor chip having a surface that has a first diaphragm region and a peripheral region, the peripheral region including a mounting region; and
a substrate having a surface with a recess;
wherein the mounting region of the semiconductor chip is mounted using a flip-chip technique onto the surface of the substrate, whereby an edge of the recess lies between the mounting region and the diaphragm region, and wherein a region below the mounting region is filled with an underfilling component, the edge of the recess functioning as a demarcation region for the underfilling component so that no underfilling component extends into the diaphragm region.

14. The semiconductor chip system as recited in claim 13, wherein in the mounting region a plurality of bondpads is provided for mounting onto the surface of the substrate by one of a soldering and an adhesive connection.

15. The semiconductor chip system as recited in claim 14, wherein the semiconductor chip is configured as a sensor chip, and wherein the recess extends to an area below the diaphragm region.

16. The semiconductor chip system as recited in claim 15, wherein the semiconductor chip is bonded on its rear surface to a glass base.

17. The semiconductor chip system as recited in claim 13, wherein, in the peripheral region, at least one support base is provided lying on the surface of the substrate.

18. The semiconductor chip system as recited in claim 13, wherein the semiconductor chip is configured as a sensor chip, and wherein the substrate is a part of a prefabricated housing.

19. The semiconductor chip system as recited in claim 18, wherein the housing is a pre-mold housing made of plastic, and wherein a lead-frame is molded into the housing.

20. The semiconductor chip system as recited in claim 18, wherein the housing has an annular sidewall region surrounding the sensor chip, and wherein the housing is closed above the sensor chip by a cover having a through hole opening.

21. The semiconductor chip system as recited in claim 18, further comprising:
an additional semiconductor chip mounted in the housing, wherein the additional semiconductor chip is molded into the housing.
